(19) United States
(12) Patent Application Publication
(10) Pub. No.: US 2004/0123896 A1
(43) Pub. Date: Jul. 1, 2004

(54) Selective heating and sintering of components of photovoltaic cells with microwaves

(75) Inventors: John Lemmon, Schoharie, NY (US); James Spivack, Cobleskill, NY (US)

Correspondence Address: FAY, SHARPE, FAGAN, MINNICH & MCKEE, LLP, 1100 SUPERIOR AVENUE, SEVENTH FLOOR, CLEVELAND, OH, 44114, US

(73) Assignee: GENERAL ELECTRIC COMPANY, Schenectady, NY

(21) Appl. No.: 10/334,866

(22) Filed: Dec. 31, 2002

(51) Int. Cl. H01L 31/00

(52) U.S. Cl. 136/252; 136/250; 438/88; 438/57

(57) ABSTRACT

In accordance with a first aspect of the invention, an article is formed by selectively sintering a layer of film material on a substrate by exposure to microwave energy.

### BACKGROUND OF THE INVENTION

1. Field of the Invention

The present invention is directed to a method of manufacturing articles having a layer of material sintered thereon.

2. Discussion of the Art

The use of microwave energy rather than conventional thermal energy in industrial processes is becoming more widespread because of rapid and economical heating that can thereby be achieved.

Recently, microwave energy has been used to alter the properties of certain materials. For example, Lin, et al. (J. Eur. Ceram. Soc., 21 (10-11), 2085-2088 (2001)) describes using microwaves to enhance the densification behavior and electrical properties of ZnO electronics ceramic materials. Similarly, Link, et al. (Adv. Sci. Technol. (Faenza, Italy) (1999), 15 (Ceramics: Getting into the 2000's pt. C), 369-378) discloses using microwave technology to control certain mechanical properties (low temperature creep and superplastic deformation) by controlling grain growth of ceramic materials during sintering by using millimeter wave technology. Other discussions relating to the effects of microwaves on various ceramic materials can be found in Tajima, et al. (Korean J. Ceramics, 4(4), 352-355, (1998)), and Bossert, et al. (Materialwiss. Nerkstofftech., 28(5), 241-245 (1997)).

With respect to sintering of materials, the use of microwaves allows for a selective approach towards sintering based upon the materials involved in the sintering's coupling constant.

Spraying solubilized metal solutions to form a ceramic coating with post-sintering is known in the art. However due to the high energy necessary for in-situ sintering, most techniques produce non-adhering powders to the substrate and require post-sintering. When sintering using conventional heating, both substrate and films are simultaneously heated. This simultaneous heating of both the substrate and the film is sometimes done at temperatures that can be detrimental to the properties of the substrate.

Accordingly, there is a need for the ability to be able to sinter materials having different coupling constants so that selective heating of the desired material can occur. This would permit the ability to selectively induce phase changes or changes in the physical properties of materials to be sintered in combinations while maintaining the integrity of the other components of the combination.

### BRIEF SUMMARY OF THE INVENTION

In accordance with a first aspect of the invention, an article is formed by selectively sintering a layer of film material on a substrate by exposure to microwave energy.

A further aspect of the invention relates to a method for selectively sintering a layer of film material on a substrate wherein the film is applied to the substrate and exposed to microwave energy that is tuned for heating the film material.

Another aspect of the invention relates to a method for selectively sintering a film material on a substrate wherein the film material is nebulized and heated by microwave energy to a temperature sufficient to cause sintering of the film material prior to application to the substrate.

An additional aspect of the invention relates to a method for selectively sintering a film material on a substrate wherein the substrate material is exposed to microwave energy for a period sufficient to heat the substrate to a temperature sufficient to cause sintering of the film material. The film material is then applied to the heated substrate to form a sintered layer.

A further aspect of the invention relates to a photovoltaic cell which is produced by utilizing the selective sintering methods of the present invention.

These and other aspects and objects of the invention will become apparent upon reading and understanding of the detailed description of the invention.

### DETAILED DESCRIPTION OF THE INVENTION

In accordance with the present invention, microwave energy is used for the rapid sintering and densification of thin or thick film materials on substrate materials.

The method of applying the film of sintered material to the substrate can be accomplished using a number of different methods, all of which utilize microwaves for selectively heating the film material or the underlying substrate.

According to one aspect of the invention, particles of a material to be deposited as a film onto a substrate material are generated in a nebulized plume. The particles in the nebulized plume can be passed through a preheating mechanism prior to exposure to microwave energy in order to reduce the heating time required by the microwave energy. The microwave energy is then applied to further heat the nebulized particles to a temperature sufficient to cause sintering of the film material. The heated particles then are allowed to deposit on a substrate to form a sintered film thereon.

In a different aspect of the invention, the microwave energy is focused on the underlying substrate which carries the sintered layer. The underlying substrate is heated by the microwave energy to a point at which, when a material to be sintered onto the substrate is applied to the substrate, the material is thereby sintered to the superheated substrate.

In a further embodiment of the invention, thin films (or green types) of various materials, such as, for example, photovoltaic materials, may be sintered to an underlying substrate material by applying the thin film to the substrate and exposing said thin film to microwave energy. The microwave energy is such that it causes the thin film to be sintered to the underlying substrate without causing appreciable heating to the substrate itself.

The types of materials which can be selectively sintered utilizing the microwave sintering techniques of the present invention include, but are not necessarily limited to, solubilized metal salt solutions, slurries, organometallics, tape cast rubbers (polymer-metal or metal oxide containing materials), or metal inks. Examples of such materials include, but are not limited to nanocrystalline titania films, semi-conductor films, polymer coatings, screen printed or tape cast metal oxide materials and the like. Film thicknesses in the range of about 100 nm to about 1 mm can be achieved by the microwave sintering method of the invention.

The substrate material upon which the sintering takes place can be formed from materials including, but not limited to, semi-conducting thin films on glass or a transparent, structural performance polymeric supports. The semi-conducting material can be a semi-transparent, inorganic, polymeric or a combination of both. In particular, the semi-conducting film may be doped or undoped titania, zinc oxide, tin oxide or a mixed slurry of inorganic oxides, or oxide precursors, with an organic polymer or small oligomer and a dispersing agent. Substrate materials, which are typically utilized in the manufacture of multi-component photovoltaic cells, are particularly suited for this application. In particular, materials including, but not limited to, glass and polymeric substrates are useful as substrates according to the invention. Polymeric materials useful as substrate materials include, but are not limited to, polyethylene, polycarbonate and poly methyl methacrylate.

The use of microwaves for the sintering of multi-component devices provides the advantages of being able to selectively heat and sinter individual components of such devices while maintaining the integrity of the other components. This is not possible with conventional heating as the entire device is exposed to heat from a conventional source, such as a furnace or oven, thereby exposing all components to temperatures which may be detrimental to the physical properties of certain components of a given device.

The microwave energy can be adjusted and optimized to selectively affect the individual components of a multi-component device. Parameters of microwaves which may be altered to achieve selectivity include, but are not limited to, frequency, power, and wave guides. By controlling and adjusting these parameters of the microwaves, sintering conditions for selectively sintering particular components of a multi-component device may be optimized.

The types of devices in which this sintering process is useful includes those types of multi-component devices in which a film of material is adhered and sintered to a substrate. Typically, the thin film and the substrate have different physical properties wherein conventional sintering processes may be detrimental to one or more of the components. One particular area of teclmology where the selective microwave sintering process is appreciated is in the construction of photovoltaic cell components. Typically, the substrate materials used in photovoltaic cells are of a lower melting point than the materials which are to be sintered thereon. As such, the high temperatures required to sinter photovoltaic type coatings onto substrates in conventional sintering processes can be detrimental to the underlying substrate. For example, nanocrystalline titania films which are sintered onto glass or polymeric substrates will benefit from the selective microwave sintering process of the invention as the nanocrystalline titania particles have a much higher phase change temperature than either of the mentioned substrate materials. By heating a nebulized plume of the titania particles by exposure to microwaves prior to deposition on the surface of the underlying substrate, the integrity of the underlying substrate upon which the superheated titania particles are deposited as a sintered layer is maintained.

Ceramic tapes, screen printed metal oxides, metal inks and slurries, also the metal particle plume, can be passed through a flame or plasma to assist in sintering.

While the invention has been described herein relative to its preferred embodiments, it is of course contemplated that modifications of, and alternatives to, these embodiments, such modifications and alternatives obtaining the advantages and benefits of this invention, will be apparent to those of ordinary skill in the art having reference to this specification. It is contemplated that such modifications and alternatives are within the scope of this invention as subsequently claimed herein.

What is claimed is:

1. A method for selective sintering of film materials on a substrate wherein said film materials are susceptible to heating by microwave energy comprising the steps of:
a) applying a layer of the film material to a substrate to form an initial coated product;
b) exposure of said initial coated product to microwave energy which is tuned for heating said film material;
wherein said film material is thereby selectively sintered on said substrate.

2. The method of claim 1 wherein said substrate is glass or a transparent, structural performance polymeric material.

3. The method of claim 2 wherein said glass or polymeric substrate is coated with a semi-transparent and semi-conductive thin film.

4. The method of claim 3 wherein said polymeric material is selected from polyethylene, polycarbonate, and poly methyl methacrylate.

5. The method of claim 1 wherein the film material comprises mixed slurries of inorganic oxides, or oxide precursors, with an organic polymer or small oligomer and dispersing agent.

6. The method of claim 1 wherein the film material is a semi-conductor material.

7. The method of claim 6 wherein the semiconductor material is selected from doped or undoped titania, zinc oxide, and tin oxide.

8. A method for selective sintering of film materials on a substrate wherein said film materials are susceptible to heating by microwave energy comprising the steps of:
a) generating small particles of said film material in a nebulized plume to form nebulized film particles;
b) exposing said film material particles in said nebulized plums to microwave energy which is sufficient to heat said film material particles to a temperature sufficient to cause sintering of said film material thereby forming a heated nebulized film material;
c) allowing the heated nebulized film material to deposit on the substrate material;
wherein the heated nebulized film material would coat the substrate as a sintered film.

9. The method of claim 8 wherein said substrate is glass or a transparent, structural performance polymeric material.

10. The method of claim 9 wherein said glass or polymeric substrate is coated with a semi-transparent and semi-conductive thin film.

11. The method of claim 8 wherein said polymeric material is selected from polyethylene, polycarbonate, and poly methyl methacrylate.

12. The method of claim 8 wherein the film material comprises mixed slurries of inorganic oxides, or oxide precursors, with an organic polymer or small oligomer and dispersing agent.

13. The method of claim 8 wherein the film material is a semi-conductor material.

14. The method of claim 13 wherein the semiconductor material is selected from doped or undoped titania, zinc oxide, and tin oxide.

15. The method of claim 8 wherein the particles of film material generated in the nebulized plume are preheated prior to exposure to microwave energy.

16. The method of claim 15 wherein the preheating is accomplished by passing the nebulized film particles through an arc, plasma or flame.

17. The method of claim 8 wherein the sintered film material is from about 100 nm to about 1 mm thick.

18. A method for selective sintering of film materials on a substrate material wherein said substrate material is susceptible to heating by microwave energy comprising the steps of:
a) exposing the substrate material to microwave energy for a period of time which is sufficient to heat said substrate material to a temperature sufficient to cause sintering of said film material, thereby forming a heated substrate;
b) applying the film material to the heated substrate;
wherein upon application of the film material to the heated substrate, the film material melts and adheres to the heated substrate as a sintered film.

19. The method of claim 18 wherein said substrate is glass or a transparent, structural performance polymeric material.

20. The method of claim 19 wherein said glass or polymeric substrate is coated with a semi-transparent and semi-conductive thin film.

21. The method of claim 18 wherein said polymeric material is selected from polyethylene, polycarbonate, and poly methyl methacrylate.

22. The method of claim 18 wherein the film material comprises mixed slurries of inorganic oxides, or oxide precursors, with an organic polymer or small oligomer and dispersing agent.

23. The method of claim 18 wherein the film material is a semi-conductor material.

24. The method of claim 23 wherein the semiconductor material is selected from doped or undoped titania, zinc oxide, and tin oxide.

25. The method of claim 18 wherein the application of the film material to the heated substrate is by spray coating, printing or doctor blading.

26. A product produced according to the process of claim 1.

27. The product of claim 26 which is a photovoltaic cell.

28. A product produced according to the process of claim 8.

29. The product of claim 28 which is a photovoltaic cell.

30. A product produced according to the process of claim 18.

31. The product of claim 30 which is a photovoltaic cell.
